(19) United States
(12) Patent Application Publication
(10) Pub. No.: US 2008/0143442 A1
(43) Pub. Date: Jun. 19, 2008

(54) Electrical Circuit

(76) Inventors: Erik Hemmendorff, Molndal (SE); Hakan Berg, Goteborg (SE); Karin Gabrielson, Lindome (SE)

Correspondence Address: ERICSSON INC., 6300 LEGACY DRIVE, M/S EVR 1-C-11, PLANO, TX, 75024, US

(21) Appl. No.: 11/815,731

(22) PCT Filed: Feb. 7, 2005
(86) PCT No.: PCT/SE05/00150

§ 371 Date: Jan. 4, 2008

(51) Int. Cl. H03G 3/00; H03F 3/04

(52) U.S. Cl. 330/284; 330/296

(57) ABSTRACT

The present invention relates to a circuit for processing a signal and comprising an amplifier (20) having an input and an output. The circuit further comprises a first switching arrangement (S3, T3) and a second switching arrangement (S2, T2). The first switching arrangement being arranged between said input and ground and said second switching arrangement being arranged between said output and ground. The switching arrangements are operatively arranged to connect said input and output to said ground so that said amplifier attenuates said signal.

### TECHNICAL FIELD OF THE INVENTION

The present invention relates to an electrical circuit and in particular a combined amplifier and attenuation circuitry, especially for high frequency applications.

### BACKGROUND OF THE INVENTION

Amplifiers are well known and widely used in different applications with a need for amplifying signals.

In some applications, if there is a need for high and low gain modes, an amplifier 10 followed by a step attenuator 11 can be used, as illustrated in FIG. 1. In both high and low gain modes, the amplifier amplifies the signal while the attenuator is active only in the low gain mode. This means that the amplifier will always consume power, which can be a problem for multi-module systems. Another disadvantage, especially in integrated circuits (chips), is that since the signal is first amplified and then attenuated to a high degree, it may just as well take another uncontrolled path on the chip, causing so called EMC (Electromagnetic Compatibility) problem. On the other hand if the amplifier is turned off, partly or completely, the matching will be degraded.

The closest prior art disclose combinations of amplifiers and attenuators. For example: WO 96/31946, which relates to a non-linearity of a voltage-controlled non-linear amplifier/attenuator, is compensated by placing a non-linear circuit in the feedback path of an operation amplifier of a linearizer. The circuit includes one or more differential amplifiers connected in parallel. A pure attenuation mode circuit is not concerned.

According to GB 2 57 907, a high-frequency switching circuit is arranged comprising a high-frequency amplifying transistor for amplifying a high-frequency signal applied thereto, a switching diode connected between a power supply and a collector of the high-frequency amplifying transistor in the forward direction with respect to a current flowing into the collector through the diode, first means for deriving an output signal of the high-frequency switching circuit through the switching diode, and second means for causing the high-frequency amplifying transistor to stop its high-frequency amplifying operation to perform its attenuation operation. Thus, this invention relates to a switching arrangement with attenuation ability.

### SUMMARY OF THE INVENTION

The main object of the present invention is to provide a novel circuit design, which eliminates the need for designing and implementing both an amplifier and an attenuator separately. The solution according to the preferred embodiments of the present invention allows minimal power consumption for the attenuator mode, which reduces heat in the circuit. Power and heat reductions are desired to be as low as possible. Additionally, the EMC-problem as mentioned earlier is solved, as the current path is controllable. Moreover, the solution according to the preferred embodiments saves space on integrated circuits.

The above problems are solved and advantages are achieved using a novel circuit design in which an amplifier circuit is provided with attenuator functionality and a control circuit.

Thus, in one preferred embodiment of the invention, the circuit comprises an amplifier having an input and an output, first switching arrangement and a second switching arrangement. The first switching arrangement is arranged between the input and ground and the second switching arrangement arranged between the output and ground. Means for controlling the first and second switching arrangements is arranged and connects the input and output to the ground so that the amplifier attenuates the signal. Most preferably, switching arrangements are transistors. The means for controlling the first and second switches is a control circuit. In on embodiment, the control circuit operates as a bias controller and sets suitable gate/base voltage for the transistors in both operation modes. In a preferred embodiment, the control circuit is designed as a level shifter.

The invention also relates to an integrated circuit comprising an aforementioned circuit.

The invention also relates to an electrical circuit comprising a transistor, resistors, first set of capacitors, and chocks. The transistor has: a first terminal being grounded, a second terminal connected to an input signal to be processed through chokes and a capacitance, a third terminal for an output signal through second set of capacitors, a circuit of a capacitor and resistor connected between terminals the transistor to provide a bias through the resistors. Switching means are connected to the first and second terminals. Means for controlling a bias of the first terminal for turning off the transistor are arranged.

According to one aspect, the invention relates to a method of processing a input signal into two states, a first state comprising amplification of the input signal and a second state comprising attenuation of the input signal. The method comprises controlling a first switching arrangement connected to an input of an amplifier and a second switching arrangement connected to an output of the amplifier such that the input and output are grounded.

### BRIEF DESCRIPTION OF THE DRAWINGS

In the following, the invention will be further described in a non-limiting way with reference to the accompanying drawings in which:

FIG. 1 schematically illustrates a circuit design according to prior art,

FIG. 2 is a schematic illustration of a circuit according to a first embodiment of the invention,

FIG. 3 is a schematic illustration of a circuit according to a second embodiment of the invention,

FIG. 4 is a schematic illustration of an equivalence circuit in the amplifier mode according to the first and second embodiments in FIGS. 2 and 3,

FIG. 5 is a schematic illustration of an equivalence circuit in the attenuator mode according to the first and second embodiments in FIGS. 2 and 3,

FIGS. 6-9 illustrate simulation and measurement results of a circuit according to a first embodiment of the invention.

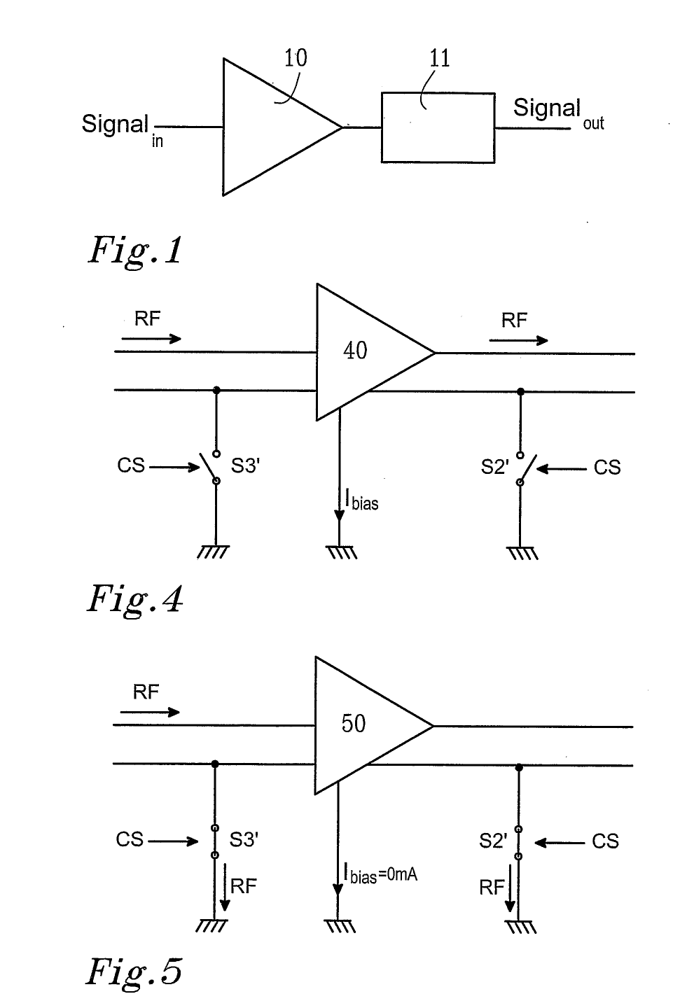

### DETAILED DESCRIPTION OF THE EMBODIMENTS

In the following, the invention is detailed with reference to schematically embodied circuits using FETs (Field Effect Transistors). However, the invention is not limited to FETs and can be realized using any type of transistors with respect to the desired applications. Thus, depending on the transistor type, it is appreciated by the skilled person that the type and value of the peripheral components may vary.

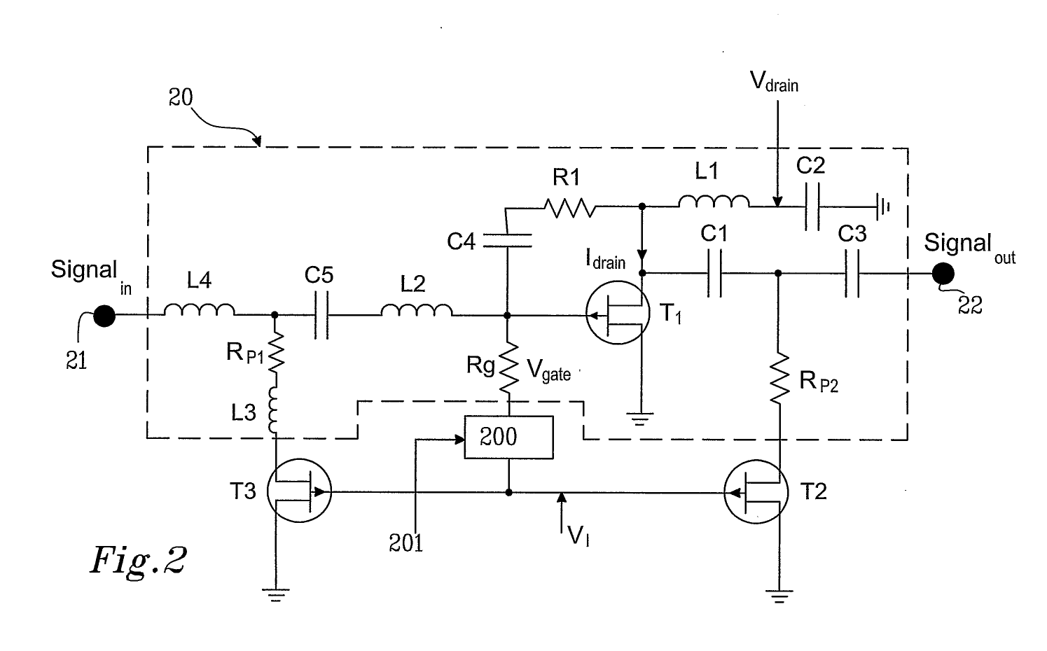

FIG. 2 illustrates a circuit according to one preferred embodiment. The amplifier portion, designated 20, comprises the transistor T1, resistors R1 and Rg, capacitors C1, C2 and C4, and chocks (inductances) L1 and L2.

The amplifying transistor T1 is grounded through its source. The input signal to be amplified, Signal_{IN}, is connected to the gate of the transistor T1 through chokes L4 and L2 and capacitance C5. The output signal (Signal_{OUT}) is decoupled from the drain of the transistor T1 through capacitors C1 and C3. A circuit comprising a capacitor C4 and resistor R1 is connected in series between the gate and the drain of the transistor T1 so as to provide a bias through a series of resistors R1 and Rg. The drain of the transistor T1 is furthermore grounded through bypass capacitor C2 and inductance L1.

The equivalence circuit of FIG. 4 illustrates the operation of the amplifier. RF (radio frequency) designates the processed signal. As shown, the switching transistors T2 and T3, illustrated by switches S2′ and S3′, are open and consequently the amplifier 40 functions as a normal amplifier and input RF signal passes through it, is amplified. CS designates a switch control signal.

The additional circuitry, which allows the amplifier circuit to operate as an attenuator comprises transistors T2 and T3 and a controlling circuit 200, which controls the switching transistors, T2 and T3. By changing the voltage in the node V₁ as well as controlling the gate bias of the RF-transistor T1, it is turned on or off.

The control circuit 200 is connected to the gates of the transistor T1-T3. The sources of the transistors T2 and T3 are grounded and their drains are connected to the gate and drain of the amplifying transistor, respectively. The control circuit may be arranged to receive a control signal 201. The control circuit may also be substituted with an external control signal.

In the amplifier mode, the two transistors T2 and T3 are switched off by means of the control circuit 200 and the amplifying transistor T1 operates normally and the circuit operates as an amplifier.

To operate as attenuator, the transistors T2 and T3 are in conducting state by means of the control circuit 200. When T2 and T3 conduct, Signal_{IN} is connected to ground through resistors R_{P1}, choke L3 and R_{P2} and the amplifying transistor T1 is turned off. Thus, the signal through the entire circuit is attenuated.

The equivalence circuit of FIG. 5 illustrates the function of the attenuator. As shown, the switching transistors T2 and T3, illustrated by switches S2′ and S3′, are closed and consequently the RF signals are conducted through the switches S2′ and S3′ (after amplifier 50) to ground causing the signal to attenuate. CS designates a switch control signal.

Normally, a transistor has very different return loss depending on the gate voltage. In the circuit according to the present invention, the gate voltage varies between two max values. Consequently, it is of most important to have a network, which always allows good return loss regardless of the gate voltage (V_{gate}) of the transistor. For this reason, the resistor RP1 can be chosen to have a suitable value, e.g. in this embodiment close to 50Ω, in order to provide a good return loss at the input terminal 21 when the entire circuit operates as attenuator. Analogous is applicable to RP2 at the output terminal 22.

The control circuit 200 operates as a bias controller and sets suitable gate/base voltage for the transistors in both operation modes. The control circuit may be designed as a level shifter in one embodiment.

Table 1 discloses examples of the control signal and the amplifier transistor signal values:

TABLE 1

| | Amplifier ON | Attenuator ON |
|---|---|---|
| BIAS | Control signal = 0 V | Control signal = 3 V |
| V_{gate} [V] | −0.5 | −2.0 |
| V_{I} [V] | −2.0 | 0 |
| V_{drain} [V] | 3.5 | 3.5 |
| I_{drain} [mA] | 48 | 0 |

Accordingly, a good amplification and attenuation is achieved.

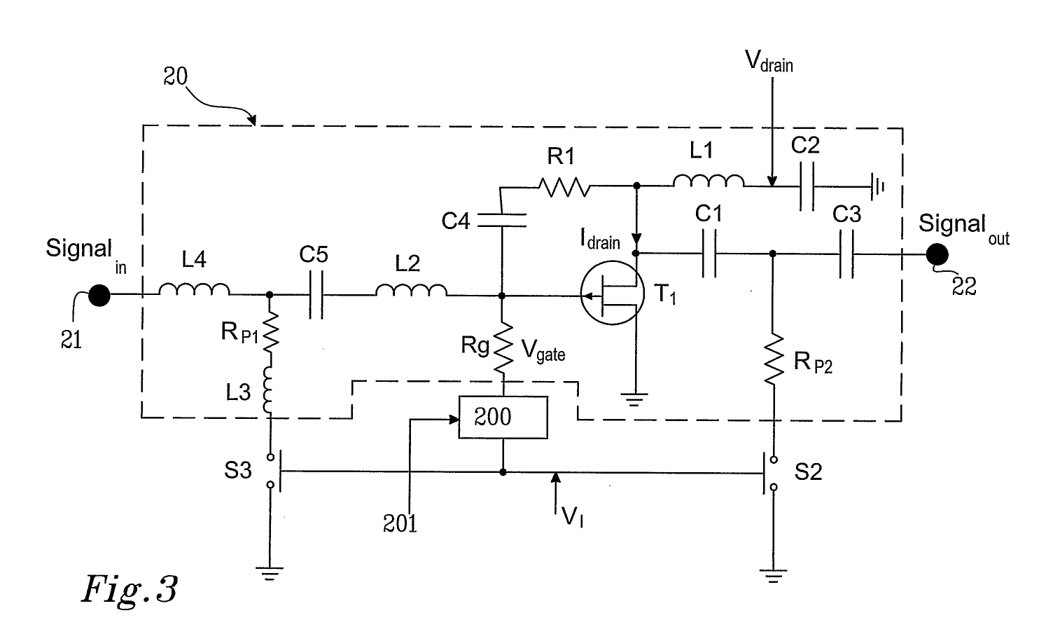

FIG. 3 is a second embodiment of the invention in which same references as used in FIG. 2 designate same parts. In this case, the switching transistors T2 and T3 are substituted by switches S2 and S3, respectively. The switches may comprise any kind of RF-switches. The control circuit 200 controls the switches S2 and S3. The circuit operates in the same way as the one described earlier. The difference is that the switches are controlled in a suitable way by the control circuit and conduct directly to the ground when closed.

The parameters L₁, L₂, L₄, C₁, C₂, C₃, C₄, R₁ and R_{g} in FIGS. 2 and 3 are chosen to achieve desired performance of the transistor in the amplifying state (traditional amplifier design). The parameters R_{P1}, R_{P2} and L₃ in FIGS.2 and 3 are so chosen that a good matching is achieved in the attenuator state. These components may be replaced by networks comprising resistors, capacitors or inductors or whatever needed to achieve a good match in the attenuator state.

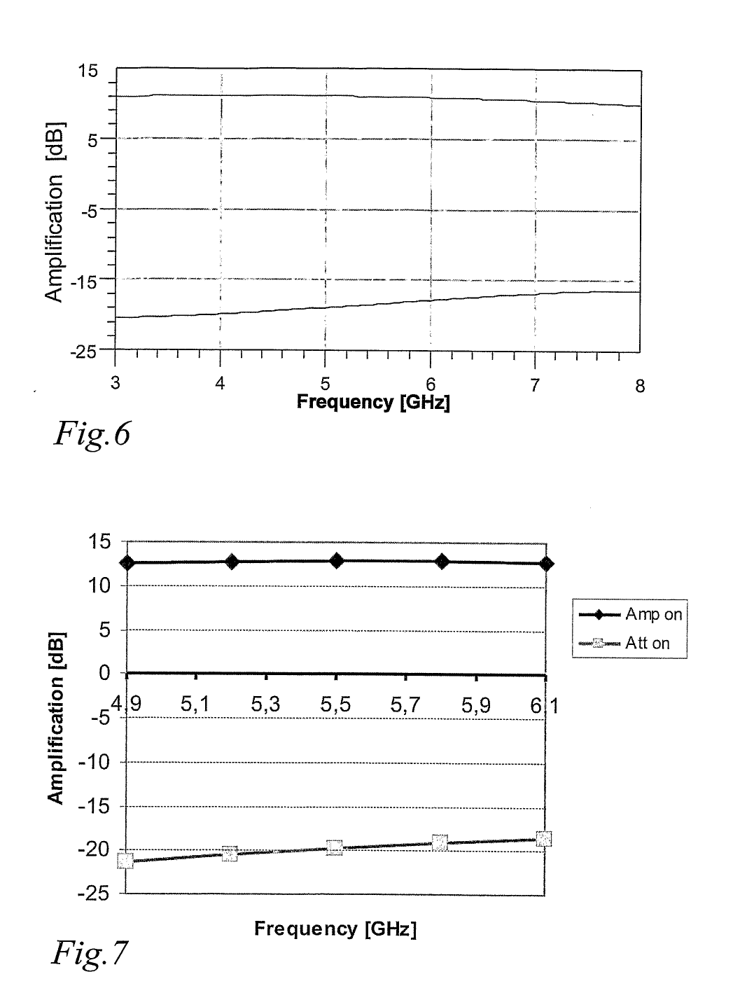

FIGS. 6 to 9 illustrate simulated and measured values for one circuit setup. FIG. 6 is simulated gain at the on and off states for the amplifier between 3 GHz to 8 GHz. The upper graph shows amplifier on state and lower graph attenuator on state (amplifier off). The corresponding measured values between 4.9 GHz to 6.1 GHz are shown in FIG. 7. It is evident that the measured values agree with the simulated values very well.

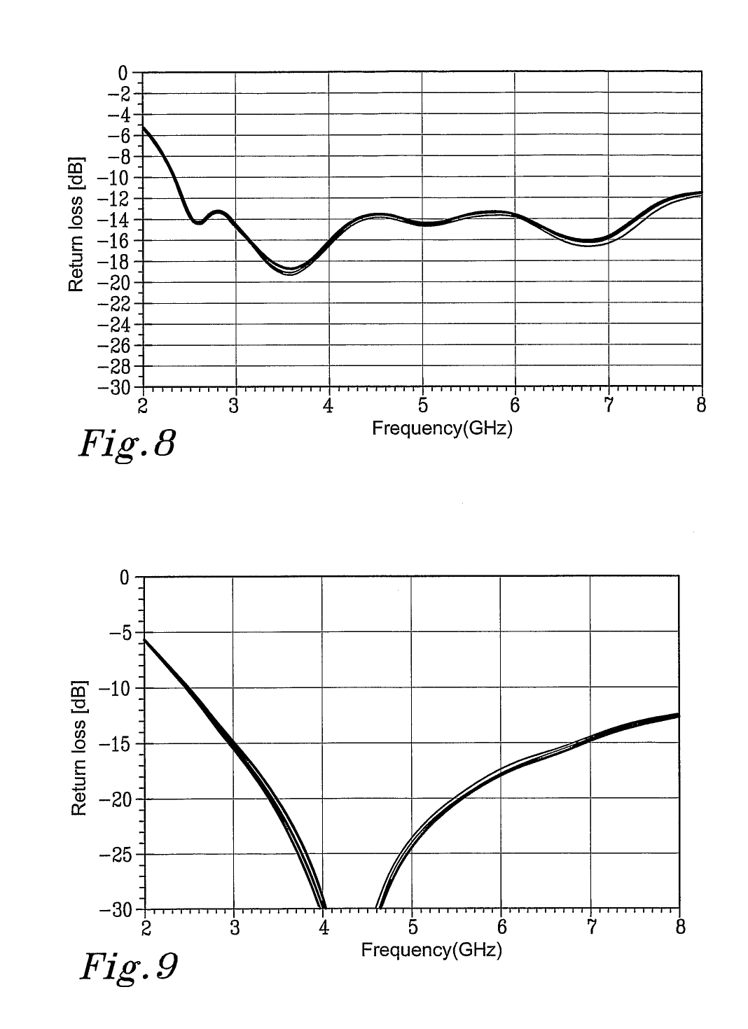

FIG. 8 shows measured output return loss at the amplifier on state in the frequency range of 2-8 GHz. FIG. 9 shows measured output return loss at the amplifier off state (attenuator on) in the frequency range of 2-8 GHz. The simulated and measured return loss agrees very well, assuming that the scales are logarithmic.

The invention is not limited to the shown embodiments but can be varied in a number of ways without departing from the scope of the appended claims and the arrangement and the method can be implemented in various ways depending on application, functional units, needs and requirements etc.

1. A circuit for processing a signal comprising amplifying and attenuating functionality having an input and an output, said circuit further comprising:
a first switching arrangement,
a second switching arrangement,
an amplifying arrangement
said first switching arrangement being arranged between said input and ground and said second switching arrangement being arranged between said output and ground,
means for controlling said first and second switching arrangements and connecting said input and output to said ground so that said amplifier attenuates said signal and,
wherein said means for controlling said first and second switching arrangements is adapted to set a suitable voltage for said first and said second switching arrangement and for said amplifying arrangement in both operation modes.

2. The circuit of claim 1, wherein said switching arrangements are transistors.

3. The circuit of claim 1, wherein said means for controlling said first and second switches is a control circuit.

4. The circuit of claim 3, wherein the control circuit operates as a bias controller and sets suitable gate/base voltage for the transistors in both operation modes.

5. The circuit of claim 3, wherein the control circuit is designed a level shifter.

6. An integrated circuit comprising a circuit according to claim 1.

7. An electrical circuit comprising a transistor, resistors, first set of capacitors, and chocks, transistor having:
a first terminal being grounded,
a second terminal connected to an input signal to be processed through chokes and a capacitance,
a third terminal for an output signal through second set of capacitors,
a circuit of a capacitor and resistor connected between terminals said transistor to provide a bias through said resistors,
switching means connected to said first and second terminals, and
means for controlling a bias of said first terminal for turning off said transistor.

8. The circuit of claim 7, wherein said switching means comprises transistor.

9. A method of processing a input signal into two states, a first state comprising amplification of said input signal and a second state comprising attenuation of said input signal, the method comprising controlling a first switching arrangement connected to an input of an amplifier and a second switching arrangement connected to an output of said amplifier such that said input and output are grounded by said first and second switching arrangements being adapted to set a suitable voltage for said first and second switching arrangement and for said amplifier in both operation modes.
